(19) United States
(12) Patent Application Publication
(10) Pub. No.: US 2018/0050917 A1
(43) Pub. Date: Feb. 22, 2018

(54) POLYSILICON FILAMENT BONDING DEVICE USING POLYSILICON FRAGMENTS

(71) Applicant: OCI COMPANY LTD., Seoul (KR)

(72) Inventors: Byung-Chang KANG, Seongnam-si, Gyeonggi-do (KR); Chang-Ryol KIM, Seongnam-si, Gyeonggi-do (KR)

(21) Appl. No.: 15/322,324

(22) PCT Filed: Jun. 26, 2015
(86) PCT No.: PCT/KR2015/006587

§ 371 Date: Dec. 27, 2016

(30) Foreign Application Priority Data
Jun. 27, 2014 (KR) 10-2014-0079452

(51) Int. Cl. C01B 33/035; B23K 20/06; B23K 20/26; C30B 33/06

(52) U.S. Cl. CPC C01B 33/035; C30B 33/06; B23K 20/26; B23K 20/06

(57) ABSTRACT

The present invention relates to a polysilicon filament manufacturing device, and more specifically, to a polysilicon filament binding device for manufacturing a polysilicon filament having a desired length by connecting polysilicon fragments cut from damage, etc. The present invention provides a polysilicon filament binding device comprising: a body part having a barrel-shape; a guide part provided inside the body part, guiding incoming polysilicon fragments; and a main light source for heating the binding surfaces of the polysilicon fragments.

### TECHNICAL FIELD

The present disclosure relates to a polysilicon filament bonding device, and more particularly, to a polysilicon filament bonding device for manufacturing a polysilicon filament with a desired length by bonding polysilicon fragments separated due to damage or the like.

### BACKGROUND ART

When polysilicon is prepared using the Siemens method, a polysilicon filament is required. A currently used filament is manufactured using the Czochralski (CZ) process or a floating zone (FZ) method or a manufactured polysilicon rod is processed and used according to the filament standard.

In the case of the CZ method or FZ method of manufacturing a filament by melting polysilicon, in order to form a long filament, a reactor with a length equal to or greater than the filament is required and the possibility that a filament is damaged is high due to the characteristics of a filament shape during manufacture thereof.

In particular, when a filament is processed and used directly from a polysilicon rod, it is difficult to prepare a polysilicon rod with a length equal to or greater than a length of a filament.

In addition, the possibility that a slim and long filament breaks upon being installed in a reactor is very high and, in this case, there is a limit in that reuse of the breaking filament is not possible in reality.

As a cited reference, Korean Patent Application Publication No. 10-2013-0019568 (published on Feb. 27, 2013) discloses a “Method and apparatus for preparing polysilicon.”

### DISCLOSURE

### Technical Problem

It is an object of the present disclosure to provide a device for bonding polysilicon fragments to form a polysilicon filament.

It is another object of the present disclosure to provide a polysilicon filament bonding device for bonding polysilicon fragments without use of impurities.

### Technical Solution

In accordance with one aspect of the present disclosure, a polysilicon filament bonding device includes a body portion formed like a cylinder, a guide portion disposed in the body portion and configured to guide polysilicon fragments brought into the body portion, and a main light source for heating a bonding surface of the polysilicon fragments.

The polysilicon filament bonding device may further include an auxiliary light source for preliminarily heating a polysilicon fragment accommodated in the body portion.

The auxiliary light source may be arranged so as not to interfere with the guide portion.

When the body portion includes a reflective surface disposed on an internal surface thereof, a heating effect using an auxiliary light source may be further enhanced.

The polysilicon filament bonding device may further include a light concentrator for concentrating light emitted from the main light source to a bonding surface.

The body portion may include a sight glass for observing a bonding surface of the polysilicon filament and may further include a fixer for fixing the polysilicon fragment.

The guide portion may be formed of a polysilicon material.

The guide portion may include a frame and a plurality of rollers rotatably connected to the frame and portions of the guide portion may be arranged in the form of a square so as to uniformly support an outer circumferential surface of the polysilicon filament.

The guide portion may be detachably formed on the body portion and may be replaceable according to a diameter of the polysilicon fragment.

The polysilicon filament bonding device may further include a guide bar formed to be inserted into the body portion to a predetermined depth and having an end positioned at a heated region of the main heat source upon being inserted into the body portion.

### Advantageous Effects

The present disclosure provides a device for forming a polysilicon filament by bonding a polysilicon fragment without impurities so as to reduce manufacturing costs of the polysilicon fragment.

### DESCRIPTION OF DRAWINGS

FIG. 1 is a diagram illustrating a concept of a polysilicon filament bonding device using a polysilicon fragment according to an exemplary embodiment of the present disclosure.

FIG. 2 is a perspective view of a polysilicon filament bonding device using a polysilicon fragment according to an exemplary embodiment of the present disclosure.

FIG. 3 is a cross-sectional view of a polysilicon filament bonding device using a polysilicon fragment according to an exemplary embodiment of the present disclosure.

FIG. 4 is a cross-sectional view of a polysilicon filament bonding device using a polysilicon fragment according to another exemplary embodiment of the present disclosure.

FIG. 5 is a plan view of a polysilicon filament bonding device using a polysilicon fragment according to another exemplary embodiment of the present disclosure.

FIG. 6 is a cross-sectional view of a guide bar of a polysilicon filament bonding device using a polysilicon fragment according to an exemplary embodiment of the present disclosure.

### EXPLANATION OF REFERENCE NUMERALS DESIGNATING THE MAJOR ELEMENTS OF THE DRAWINGS

100: polysilicon filament bonding device
110: body portion
120: guide portion
130: main light source
140: auxiliary light source
150: fixer
160: guide bar

### BEST MODE

Terms or words used herein shall not be limited to having common or dictionary meanings, and have the meanings corresponding to technical aspects of the embodiments of the present disclosure so as to most suitably express the embodiments of the present disclosure. In addition, embodiments described in the specification and configurations illustrated in the drawings are merely an exemplary embodiment of the present disclosure and are not limited thereto and, thus, it will be understood by those of ordinary skill in the art that various changes and equivalents in form and details may be made therein at the filing time of the application.

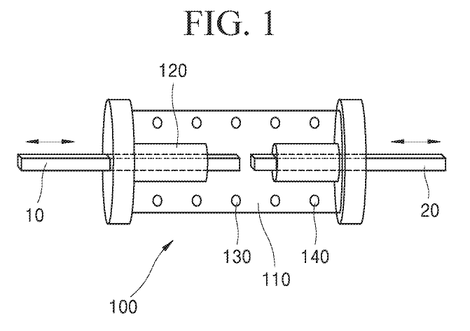

FIG. 1 is a diagram illustrating a concept of a polysilicon filament bonding device using a polysilicon fragment according to an exemplary embodiment of the present disclosure.

The polysilicon filament bonding device according to the present disclosure may be a device for bonding polysilicon fragments 10 and 20 to form a polysilicon filament with a desired length.

The polysilicon filament bonding device according to the present disclosure may melt and bond the two fragments 10 and 20 in the polysilicon filament bonding device 100 without impurities such as separate adhesives.

As illustrated in the drawing, the polysilicon filament bonding device 100 according to the present disclosure may include a cylindrical body portion 110, a guide portion 120 for guiding a polysilicon fragment that is formed and moved into the body portion, and light sources 130 and 140 for heating and welding the polysilicon fragment moved into the body portion.

The light sources may include a main light source 130 for heating a bonding surface to a polysilicon melting temperature or more and an auxiliary light source 140 for heating polysilicon around the bonding surface to the polysilicon melting temperature or less.

The guide portion 120 may be formed of a polysilicon material in order to prevent the bonded polysilicon filaments from being contaminated.

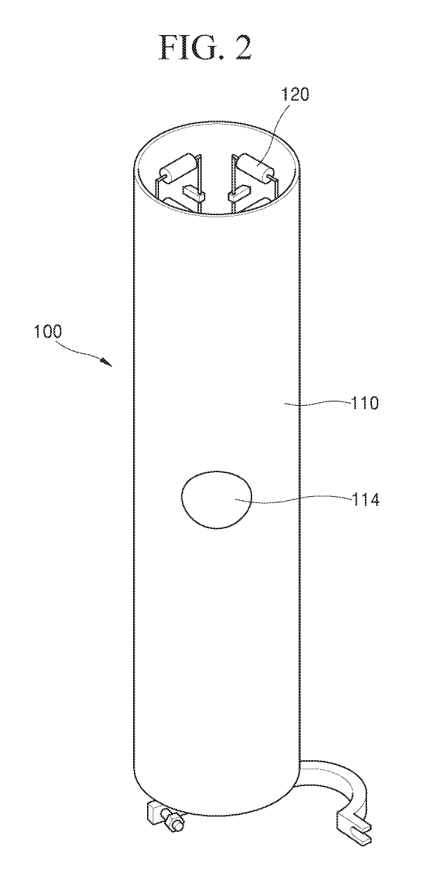

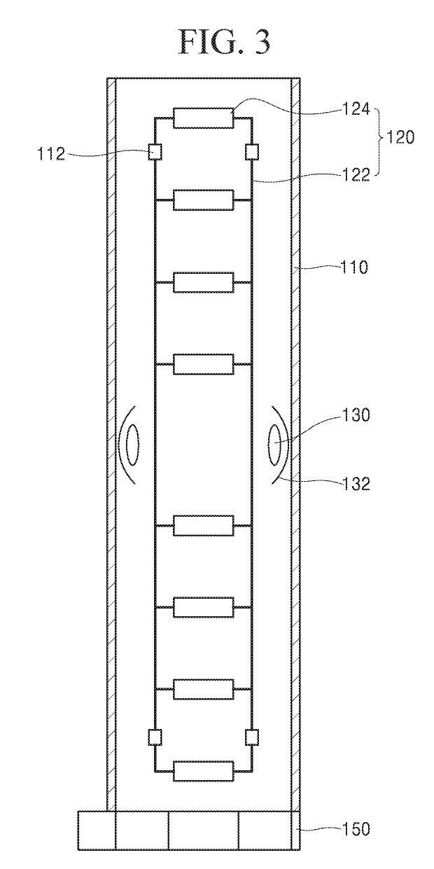

FIG. 2 is a perspective view of a polysilicon filament bonding device using a polysilicon fragment according to an exemplary embodiment of the present disclosure. FIG. 3 is a cross-sectional view of a polysilicon filament bonding device using a polysilicon fragment according to an exemplary embodiment of the present disclosure.

As illustrated in the drawings, the polysilicon filament bonding device 100 according to the present disclosure may include the cylindrical body portion 110, the guide portion 120 for guiding a polysilicon fragment that is formed and moved into the body portion, and the main light source 130 for heating a bonding surface of the polysilicon fragment moved into the body portion.

Although the drawings illustrate the case in which the polysilicon filament bonding device 100 is vertically positioned for convenience of illustration, the polysilicon filament bonding device 100 may be horizontally positioned and used as illustrated in FIG. 1.

A melting temperature of polysilicon is about 1414° C. and, in this regard, when a halogen lamp is used as a light source and a light concentrator 132 such as a concave mirror or a convex lens is used, a portion to which light is radiated may be directly heated by the light source at a temperature equal to or greater than 1414° C.

Two polysilicon fragments may be bonded to each other by processing bonding surfaces of the polysilicon fragments to be bonded so as to have corresponding shapes, inserting one of the polysilicon fragments so as to position a bonding surface at a heating portion of the main light source 130, fixing the inserted polysilicon fragment using a fixer 150, melting the bonding surface by a main light source and, then, inserting the polysilicon fragments to be bonded.

As illustrated in the drawing, the fixer 150 may be formed in the form of a clamp and may be detachably formed so as to correspond to a diameter of the polysilicon fragment. Alternatively, a separate adaptor may be detachably formed at a clamp and may be replaced according to a diameter or cross section of polysilicon to be fixed.

A polysilicon fragment used to manufacture a polysilicon filament has a circular or square cross section and, thus, it is important to bond polysilicon fragments in a straight line. The guide portion 120 may arrange the polysilicon fragments in a straight line.

To this end, portions of the guide portion 120 may be arranged in the form of a square.

The guide portion 120 may include a frame 122 and a plurality of rollers 124 and the frame 122 may be detachably fixed to a holder portion 112 formed in the body portion 110.

The frame 122 may be fixed to the holder portion 112 via sliding fitting or tight fitting.

This may be performed in order to replace the guide portion 120 so as to correspond to a diameter of a polysilicon fragment to be bonded.

The body portion 110 may include a sight glass 114 for observing a heated region of the main light source 130 therethrough. Through the sight glass 114, the bonding surface may be checked to be appropriately positioned in the heated region of the main light source 130 and a melting state of the bonding surface may be checked.

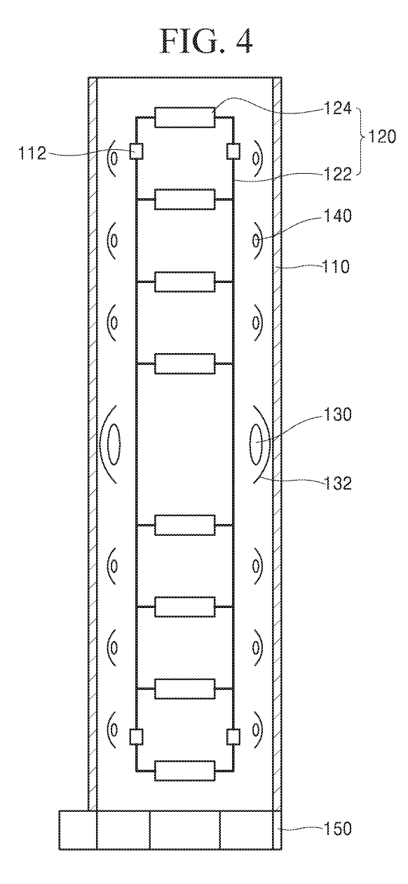

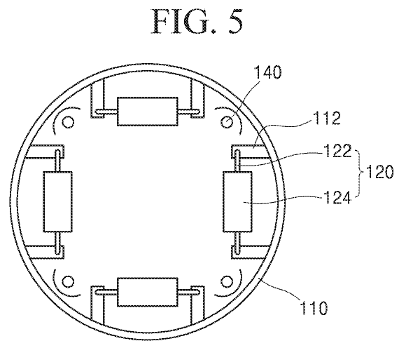

FIG. 4 is a cross-sectional view of a polysilicon filament bonding device using a polysilicon fragment according to another exemplary embodiment of the present disclosure. FIG. 5 is a plan view of a polysilicon filament bonding device using a polysilicon fragment according to another exemplary embodiment of the present disclosure.

According to the exemplary embodiment of FIGS. 4 and 5, the polysilicon filament bonding device may further include the auxiliary light source 140 for heating a polysilicon fragment accommodated in the body portion 110.

When only a bonding surface is heated to high temperature using the main light source 130, a polysilicon fragment may be damaged by thermal shock due to a local temperature difference and, thus, the polysilicon filament bonding device may further include the auxiliary light source 140 in order to heat the polysilicon fragment accommodated in the body portion 110 to an appropriate temperature.

As illustrated in FIG. 4, the auxiliary light source 140 may be disposed between the portions of the guide portion 120 and a heating temperature at which the auxiliary light source 140 is used may be in the range of 800 to 900° C. When a temperate of the auxiliary light source 140 is lower than the temperature range, the possibility that the polysilicon fragment is damaged by thermal shock due to a still high temperature difference from a bonding surface by a main light source may be increased and, when the temperature of the auxiliary light source 140 is higher than the temperature range, unnecessary energy costs may be increased.

A halogen lamp may be used as the auxiliary light source 140 like the main light source 130 and, in order to enhance a heating effect using an auxiliary light source, a reflective surface (not shown) may be disposed on an internal surface of the body portion 110. The reflective surface may reflect light emitted from the auxiliary light source 140 so as to enhance a heating effect.

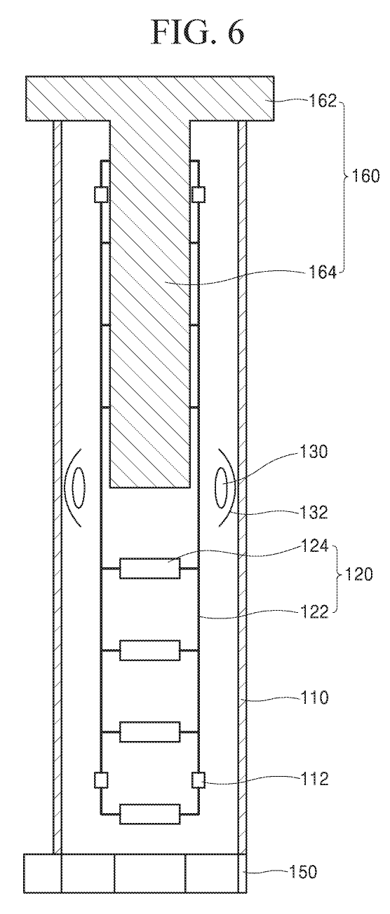

FIG. 6 is a cross-sectional view of a guide bar of a polysilicon filament bonding device using a polysilicon fragment according to an exemplary embodiment of the present disclosure.

The polysilicon filament bonding device according to the present disclosure may further include a guide bar 160. The guide bar 160 may be used to normally position a bonding surface of a polysilicon filament.

The guide bar 160 may include a head portion 162 and an insert rod 164. The head portion 162 may have a diameter with which the head portion 162 is not capable of being inserted into the body portion 110 and the insert rod 164 may have a diameter with which the insert rod 164 is capable of being inserted into the body portion 110. The insert rod 164 may have a length such that a lower end there is positioned at a central portion of a heated region of a main light source upon being completely inserted into the body portion 110.

As illustrated in the drawing, the guide bar 160 may be inserted into the body portion 110 and a polysilicon fragment may be inserted through a lower portion of the body portion 110 such that the guide bar 160 comes into contact with the insert rod of the bonding surface of the polysilicon fragment and, then, the polysilicon fragment may be fixed by the fixer 150 and the bonding surface may be fixedly positioned at the central portion of the heated region of the main light source 130.

Then, the bonding surface may be heated by the main light source 130 and the polysilicon fragment to be bonded may be inserted through an upper portion of the body portion so as to bond polysilicon fragments.

As described above, the polysilicon filament bonding device according to the present disclosure may melt and bond a plurality of polysilicon fragments without use of separate adhesives so as to manufacture a polysilicon filament with a desired length.

Accordingly, when the polysilicon filament bonding device according to the present disclosure is used, damaged polysilicon filament fragments may be reused and polysilicon filament fragments with a short length may be manufactured and bonded, thereby reducing manufacturing costs of the polysilicon filament.

The present disclosure described above may be variously substituted, altered, and modified by those skilled in the art to which the present invention pertains without departing from the scope and sprit of the present disclosure. Therefore, the present disclosure is not limited to the above-mentioned exemplary embodiments and the accompanying drawings.

1. A polysilicon filament bonding device comprising:
a body portion formed like a cylinder;
a guide portion disposed in the body portion and configured to guide polysilicon fragments brought into the body portion; and
a main light source for heating a bonding surface of the polysilicon fragments.

2. The polysilicon filament bonding device according to claim 1, further comprising an auxiliary light source for preliminarily heating a polysilicon fragment accommodated in the body portion.

3. The polysilicon filament bonding device according to claim 2, wherein the auxiliary light source is arranged so as not to interfere with the guide portion.

4. The polysilicon filament bonding device according to claim 3, wherein the body portion comprises a reflective surface disposed on an internal surface thereof.

5. The polysilicon filament bonding device according to claim 1, further comprising a light concentrator for concentrating light emitted from the main light source to a bonding surface.

6. The polysilicon filament bonding device according to claim 1, wherein the body portion comprises a sight glass for observing a bonding surface of the polysilicon filament.

7. The polysilicon filament bonding device according to claim 1, wherein the body portion further comprises a fixer for fixing the polysilicon fragment.

8. The polysilicon filament bonding device according to claim 1, wherein the guide portion is formed of a polysilicon material.

9. The polysilicon filament bonding device according to claim 1, wherein the guide portion comprises a frame and a plurality of rollers rotatably connected to the frame.

10. The polysilicon filament bonding device according to claim 9, wherein portions of the guide portion are arranged in the form of a square so as to uniformly support an outer circumferential surface of the polysilicon filament.

11. The polysilicon filament bonding device according to claim 1, wherein the guide portion is detachably formed on the body portion and is replaceable according to a diameter of the polysilicon fragment.

12. The polysilicon filament bonding device according to claim 1, further comprising a guide bar formed to be inserted into the body portion to a predetermined depth and having an end positioned at a heated region of the main heat source upon being inserted into the body portion.
